(19) United States
(12) Patent Application Publication
(10) Pub. No.: US 2008/0107825 A1
(43) Pub. Date: May 8, 2008

(54) Film-Forming Method and Recording Medium

(75) Inventors: Tadahiro Ishizaka, Albany, NY (US); Atsushi Gomi, Albany, NY (US); Satoshi Wakabayashi, Yamanashi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Tokyo Electron Limited, Tokyo (JP)

(21) Appl. No.: 11/720,404

(22) PCT Filed: Dec. 12, 2005
(86) PCT No.: PCT/JP05/22800

§ 371 Date: May 29, 2007

(30) Foreign Application Priority Data
Dec. 20, 2004 (JP) 2004-367789

(51) Int. Cl. C23C 16/505

(52) U.S. Cl. 427/578; 427/569

(57) ABSTRACT

A film deposition method by a film deposition apparatus having a process container provided with a holding table to hold a substrate to be processed therein and a showerhead part to which a radio frequency electric power for exciting plasma in the process container is applied, the method including: a film deposition process of forming a thin film containing a metal on the substrate to be processed; and a protective film forming process of forming a protective film containing a different metal on the showerhead before a film forming process.

### TECHNICAL FIELD

The present invention relates to a film deposition method for forming a thin film on an object to be processed.

### BACKGROUND ART

In recent years, with acquiring high-performance in semiconductor devices, high integration of a semiconductor device has progressed, which causes the demand for miniaturization to be remarkable, and a development in wiring rule has been progressed to an area of below 0.10 μm. With respect to a thin film used for forming a device such as a high-performance semiconductor device, a high-quality film such as, for example, a film having a small amount of impurities in the film and having a good orientation is required, and it is preferable to have a good coverage when forming a minute pattern.

As a film deposition method that satisfies such a demand, there is suggested a method of acquiring a thin film of a predetermined thickness by forming a film at a level close to an atomic layer/molecular layer by going through adsorption of process gases onto a reaction surface by alternately supplying a plurality of kinds of process gases one kind by one kind when performing film formation and repeating those processes. Such a film deposition method may be referred to as an Atomic Layer Deposition (ALD method).

An outline of a case of performing film formation according to such an ALD method can be as follows, for example. First, a process container for retaining a substrate to be processed therein is prepared, the process container having a first gas supply passage for supplying a first gas and a second gas supply passage for supplying a second gas. Then, the first gas and the second gas may be supplied alternately into said process container. Specifically, first, the first gas is supplied onto the substrate in the process container so as to form an adsorption layer on the substrate. Thereafter, the second gas is supplied onto the substrate in the process container to cause a reaction, and the processes are repeated for a predetermined number of times if necessary. According to the method, lowering of a film formation temperature can be attempted since the first gas reacts with the second gas after being adsorbed onto the substrate. Additionally, a high-quality film can be acquired with a small amount of impurities, and simultaneously, when forming a film in a minute pattern, there is no void formed due to reaction and consumption of the process gases in an upper part a hole, which has been a problem in a conventional CVD method, and a good coverage can be acquired.

As a film that can be formed by such a film deposition method, a film containing a metal can be formed by using a gas containing a metal as the first gas and a reduction gas of the first gas as the second gas, and, for example, a film made of Ta, TaN, Ta(C)N, Ti, TiN, Ti(C)N, W, WN and W(C)N, etc., can be formed.

For example, taking a case of forming a Ta film as an example, by using a compound containing Ta as said first process gas, for example, TaCl₅, and H₂ as said second process gas so as to plasma-excite the H₂ to reduce the TaCl₅, the Ta film can be formed.

Since the film formed by such a film deposition method has a good film quality and excellent in the property of coverage, for example, the film may be used as a Cu diffusion preventing film, which is formed between an insulating film and Cu when forming Cu wiring in a semiconductor device.

Patent Document 1: U.S. Pat. No. 5,916,365

Patent Document 2: U.S. Pat. No. 5,306,666

Patent Document 3: U.S. Pat. No. 6,416,822

Patent Document 4: WO00/79756

### DISCLOSURE OF THE INVENTION

Problems to be Solved by the Invention

However, for example, when a process gas is used while performing plasma-excitation, there has been a case where an internal part of the process container, for example, an electrode to which a radio frequency power is applied, is sputtered by ions and radicals generated by the plasma and scatters in the process container, which makes particles or a pollution source of a thin film to be formed. A specific example thereof is indicated below.

For example, FIG. 1(A)-(D) are an example which shows a film deposition method for forming a Ta film on a substrate to be processed by following procedure.

First, in a process shown in FIG. 1(A), a first process gas G1 made of, for example, TaCl₅, is supplied onto a substrate Su to be processed retained on a substrate holding table E1 by a showerhead part E2 placed above the substrate to be processed so as to cause the first process gas to be adsorbed onto the substrate to be processed. In this case, said showerhead part E2 can supply the process gas onto the substrate to be processed, and has a structure in which a radio frequency power is applied by a radio frequency power source R.

Next, in a process shown in FIG. 1(B), a second process gas G2 made of, for example, H₂ by said showerhead part E2 and a radio frequency power is applied to the showerhead part E2 so as to excite plasma in a gap Ga between said substrate holding table E1 and said showerhead part E2. Thus, the H₂ supplied to the gap Ga is diverged and, for example, H⁺/H*(hydrogen ions and hydrogen radicals) are formed.

Next, in a process shown in FIG. 1(C), a reaction indicated by

TaCl₅+H₂→Ta+HCl.

is generated, and a Ta film is formed on the substrate to be processed.

However, on the other hand, as shown in FIG. 1(D), a reaction indicated by

HCl→Cl⁺/Cl*+H⁺/H*

is generated, that is, the formed HCl is excited by plasma and halogen elements are activated and, for example, Cl⁺/Cl* (Cl ions and Cl radicals) are generated, thereby causing a problem in that said showerhead part E2 is etched by those. Additionally, from among the generated Cl ions and Cl radicals, an influence of sputtering by the Cl ions is especially large. This is because the radio frequency power is applied to said showerhead part E2 and a so-called self-bias potential (Vdc) is generated, thereby causing an ion bombardment to be large and increasing a sputtering rate. Thus, a material constituting said showerhead scattered by the sputtering is mixed into said substrate Su to be processed, which may result in a pollution source of the formed Ta film.

Thus, it is an issue of the present invention to provide a film deposition method which solves the above-mentioned problems.

A specific issue of the present invention is to suppress scattering of pollution source of film formation when performing film formation on a substrate to be processed by using a process gas being plasma-excited so as to enable clean and stable film formation.

Means to Solve the Problems

According to a first aspect of the present invention, the above-mentioned problems are solved by a film deposition method by a film deposition apparatus that comprises: a process container having therein a holding table for holding a substrate to be processed; and a gas supply part configured to be capable of being applied with a radio frequency electric power so as to supply a film deposition gas or a reduction gas for reducing the film deposition gas into said process container, the film deposition method comprising: a first step of supplying said film deposition gas containing a metal element and a halogen element into said process container; a second step of supplying said reduction gas into said process container; and a third step of performing film deposition on said substrate to be processed by applying a radio frequency electric power to said gas supply part to excite plasma in said process container, the film deposition method further provided with a protective film forming step of forming a protective film that protects said gas supply part from etching of said halogen element that is activated in said third step.

Additionally, according to a second aspect of the present invention, the above-mentioned problems are solved by a recording medium storing a program for causing a computer to operate a film deposition method by a film deposition apparatus that comprises: a process container having therein a holding table for holding a substrate to be processed; and a gas supply part configured to be capable of being applied with a radio frequency electric power so as to supply a film deposition gas or a reduction gas for reducing the film deposition gas into said process container, the film deposition method comprising: a first step of supplying said film deposition gas containing a metal element and a halogen element into said process container; a second step of supplying said reduction gas into said process container; and a third step of performing film deposition on said substrate to be processed by applying a radio frequency electric power to said gas supply part to excite plasma in said process container, the film deposition method further provided with a protective film forming step of forming a protective film that protects said gas supply part from etching of said halogen element that is activated in said third step.

Effect of the Invention

According to the present invention, sputtering of pollution source of film deposition is suppressed in a case where film deposition is performed on the substrate to be processed by using a process gas by being plasma-excited, thereby permitting a clean and stable film deposition.

### BRIEF DESCRIPTION OF DRAWINGS

FIG. 1(A)-(D) is a diagram illustrating a conventional film deposition method.

FIG. 2 is a diagram illustrating an example of a film deposition apparatus that performs a film deposition method according to an embodiment 1.

FIG. 3 is a diagram illustrating a cross section of a showerhead used in the film deposition apparatus of FIG. 2.

FIG. 4 is a flowchart (part 1) showing the film deposition apparatus according to the embodiment 1.

FIG. 5 is a flowchart (part 2) showing the film deposition apparatus according to the embodiment 1.

FIG. 6 is a flowchart (part 3) showing the film deposition apparatus according to the embodiment 1.

FIG. 7 is a diagram showing a relationship between a film deposition temperature and a film deposition rate of a thin film formed.

FIG. 8 is a diagram illustrating an example of a film deposition apparatus that performs a film deposition method according to an embodiment 3.

FIG. 9 is a diagram showing a relationship between a film deposition temperature and a film deposition rate of a protective film formed.

FIG. 10 is a diagram showing a relationship between a film deposition temperature and an optical refractive index of a protective film formed.

FIG. 11 shows a film deposition rate and a specific resistance value when Ti is formed on a substrate to be processed.

### EXPLANATION OF REFERENCE NUMERALS

11 process container
12 substrate holding table
12A substrate holding table support
13 showerhead part
13A showerhead main body
13B shower plate
13c, 13d, 13E gas aperture
14, 16, 100a, 100b insulator
15 exhaust port
17 radio frequency power source
17a power supply line
100, 101, 102, 200, 201, 202, 203, 205, 206, 207, 209 gas line
101A, 102A, 201A, 205A, 209A mass flow controller
101a, 101b, 102a, 102b, 201a, 201b, 203a, 203b, 202a, 203c, 205a, 205b, 206a, 207a, 207b, 207c, 209a, 209b valve

### BEST MODE FOR CARRYING OUT THE INVENTION

Next, a description will be given below of modes of carrying out the present invention based on the drawings.

### EMBODIMENT 1

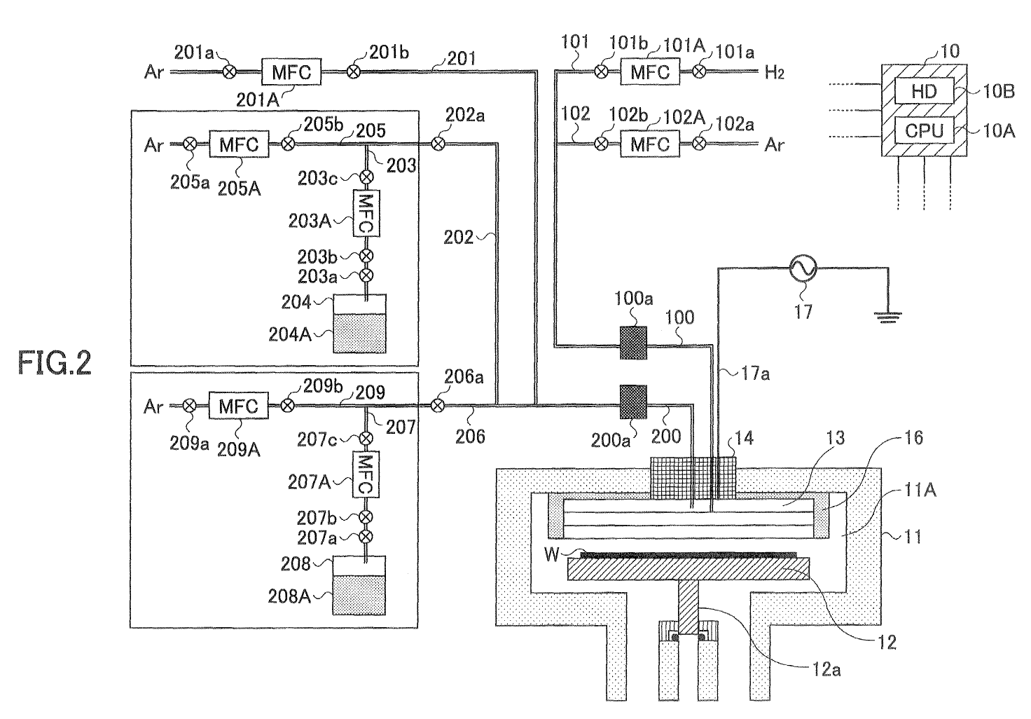

FIG. 2 is a diagram illustrating a film deposition apparatus which carries out a film deposition method according to an embodiment 1.

The film deposition apparatus shown in the figure has a process container 11 for accommodating a substrate W to be processed therein, and is configured so that a first process gas and a second process gas are supplied into a process space 11A formed in the process container 11 through a gas line 200 and a gas line 100, respectively.

Then, a film deposition is performed at a level close to an atomic layer or a molecular layer through adsorption of the process gases onto a reaction surface by supplying the process gases to said process space 11A alternately one kind by one kind through the gas line 200 and the gas line 100 so that, by repeating those processes, a thin film of a predetermined thickness can be formed on the substrate W to be processed according to a so-called ALD method. The film formed by such an ALD method can acquire a high-quality film having a small amount of impurities while a film deposition temperature thereof is a low temperature, and at the same time, a good coverage can be acquired when forming a film in a minute pattern.

Moreover, the film deposition method according to the present embodiment uses a second process gas, which reduces a first process gas containing metal, by plasma-exciting, and, thus, a reaction to reduce the first process gas is promoted, which provides an effect that a formed film quality is good.

However, conventionally, there has been a problem in that an interior of the process container, that is, for example, an electrode to which a radio frequency for exciting plasma is applied and the like are etched by ions and radicals generated in the process container. Especially, in the film deposition method according to the ALD method of which feature is that a formed film quality is good and an amount of impurities is extremely small, there has been a case in which those pollutions cause a problem.

Thus, in the present embodiment, a clean and stable film deposition is realized by forming a protective film against etching on the interior of the process container or an electrode. A specific method and details thereof will be mentioned later.

Next, considering details of the film deposition apparatus, the film deposition apparatus shown in the figure has the process container 11, which is made of, for example, aluminum, aluminum of which surface is anodized or a stainless steel, and a substrate holding table 12 of a generally circular plate shape is installed in said process container by being supported by substrate holding table supporting member 12a so that the substrate W to be processed is placed at a center of said substrate holding table 12. A heater, not shown in the figure, is incorporated into said substrate holding table 12 so as to achieve a structure in which said substrate to be processed can be heated at a desired temperature.

The process space 11A in said substrate process container 11 is vacuum-exhausted by exhaust means, not shown in the figure, connected to an exhaust port 15, so as to set said process space in a depressurized state. Additionally, said substrate W to be processed is carried into or out from said process container 11 through a gate valve, not shown in the figure, provided to said process container 11.

Moreover, a showerhead part 13 having a showerhead structure, which is a gas supply part of a cylindrical shape made of, for example, nickel, aluminum, etc., is provided in said process container 11 so as to be opposite to said substrate holding table 12, and an insulator 16 made of a ceramic such as, for example, quartz, SiN, AlN, etc., is provided on a sidewall surface of said showerhead part 14 and between the showerhead part 13 and said process container 11.

Moreover, an opening is provided on an upper wall surface of said process container 11 above said showerhead part 13, and an insulator 14 made of an insulating material is inserted therein. A lead-in line 17a connected to a radio frequency power source 17 is inserted into said insulator 14, and said lead-in line 17a is connected to said showerhead part 13 so that a structure is formed in which a radio frequency electric power is applied to said shower head part 13 by said lead-in line 17a.

Moreover, said gas line 200, which supplies the first gas to said process space 11A, and said gas line 100, which supplies the second process gas to said process space 11A are connected to said showerhead part 13 so as to be a structure in which said first process gas and second process gas are supplied to said process space 11A through the showerhead part 13. Additionally, insulators 200a and 100a are inserted into said gas line 200 and gas line 100, respectively, so as to be a structure in which the gas lines are isolated from a radio frequency electric power.

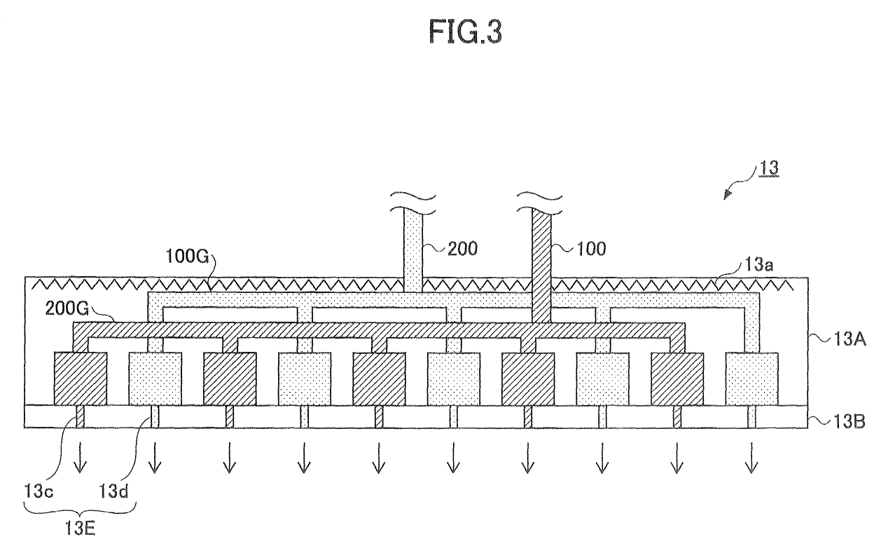

FIG. 3 is a cross-sectional view illustrating details of said showerhead part 13. It should be noted that parts explained previously are given the same reference numerals, and descriptions thereof will be omitted. Said showerhead part 13 comprises a showerhead main body 13A in which a gas flow passage 200G of the first process gas and a gas flow passage 100G of the second gas are formed, and a shower plate 13B in which gas apertures 13E consisting of a plurality of gas apertures 13c and 13d are formed.

Said gas flow passage 200G connected to said gas line 200 is further connected to the gas apertures 13c of said shower plate 13B. That is, the first process gas is supplied to said process space 11A through a first gas supply path comprised of said gas line 200 to said gas flow passage 200G and further to said gas apertures 13c. On the other hand, said gas flow passage 100G connected to said gas line 100 is further connected to the gas apertures 13d of said shower plate 13B. That is, the second process gas is supplied to said process space 11A through a second gas supply path comprised of said gas line 100 to said gas flow passage 100G and further to said gas apertures 13d.

Thus, in said showerhead part 13, the flow passages of the first process gas and the second process gas are formed independently so as to form a so-called post-mix type showerhead structure in which the first process gas and the second process gas are mainly mixed with each other in said process space 11A.

Additionally, heating means 13a comprised of, for example, a heater is provided to the showerhead part 13 so that the showerhead part 13 can be heated. For example, in a case where a metal film such as, for example, a Ta film or a film containing metal is deposited, a deposition rate depends on a temperature of an object to be deposited, and there is a tendency that the deposition rate is lower as the temperature is higher. Thus, a film thickness of a film formed on the showerhead part 13 is made thin by heating the showerhead part by the heating means 13a so as to prevent peeling of the film and generation of particles, and also acquire an effect to elongate a cycle of maintenance such as cleaning.

Moreover, as shown in FIG. 2, the gas line 200 is connected with a gas line 202, which supplies the first process gas to the gas line 200 and provided with a valve 202a, and a gas line 206, which supplies a different first process gas to the gas line 200 and provided with a valve 206a. That is, a structure is made so that two kinds of first process gases from said gas line 202 and said gas line 206 to said gas line 200, respectively, can be used by switching by opening and closing of the valves.

Further, a gas line 201, which supplied a purge gas to the gas line 200, is connected to said gas line 200.

On the other hand, a gas line 101, which supplies the second process gas to the gas line 100, and a gas line 102, which supplies a purge gas to the gas line 100, are connected to said gas line 100.

First, considering said gas line 202, a line 203 provided with a mass flow controller 203A, a valve 203a, a valve 203b and a valve 203c is connected to said gas line 202, and the line 203 is connected to a source material container 204 in which a source material 204A such as, for example, TaCl₅ is stored. The source material 204A is a source material of a thin film containing metal formed on the substrate to be processed. Additionally, a gas line 205, which is provided with a mass flow controller 205A and valves 205a and 205b to introduce a carrier gas such as Ar, is connected to said gas line 202. A structure is made in which said first process gas is supplied to said process space 11A through said showerhead part 13 together with the carrier gas such as Ar supplied from said gas line 205.

Moreover, a line 207 provided with a mass flow controller 207A, a valve 207a and a valve 207b is connected to said gas line 206, and the line 207 is connected to a source material container 208 in which a source material 208A such as, for example, TiCl₄ is stored. The source material 208A is a source material for forming a protective film which protects said showerhead part 13. Additionally, a gas line 209, which is provided with a mass flow controller 209A and valves 209a and 209b to introduce a carrier gas such as Ar, is connected to said gas line 206. A structure is made in which the first process gas different from said first process gas is supplied to said process space 11A through said showerhead part 13 together with the carrier gas such as Ar supplied from said gas line 209.

As mentioned above, the first process gas, which is a source material to form a thin film on the substrate to be processed and another first process gas, which is a source material for forming the protective film which protects said showerhead part 13, different from the first gas can be supplied into the process container from said gas line 200.

Moreover, a supply source of, for example, Ar gas, which is a purge gas, is connected to said gas line 101 for supplying the purge gas to said gas line 200, and the mass flow controller 201A and the valves 201a and 201b are provided so that an amount of flow of the supplied purge gas is controlled.

On the other hand, a supply source of, for example, H₂ gas, which is a second gas, is connected to said gas line 101 connected to said gas line 100, and the mass flow controller 101A and the valves 101a and 101b are provided so that an amount of flow of the supplied second process gas is controlled.

Moreover, a supply source of, for example, Ar gas, which is a purge gas, is connected to said gas line 102 for supplying the purge gas to said gas line 100, and the mass flow controller 102A and the valves 102a and 102b are provided so that an amount of flow of the supplied purge gas is controlled.

Moreover, operations concerning the film deposition method of the film deposition apparatus, such as the above-mentioned valves, mass flow controllers, radio frequency power source, etch, are controlled by a control device 10 incorporating a computer (CPU) 10A. Additionally, a storage medium 10B made of, for example, a hard disk is incorporated in the control device 10, and, for example, the operation of the film deposition method according to the present embodiment indicated below is performed by said computer 10A. Additionally, such a program may be referred to as a device recipe.

When forming a metal film or a film containing metal on said substrate W to be processed placed on said holding table 12, the film deposition apparatus is controlled generally as follows.

First, a first process gas containing metal is supplied to said process space 11A through said gas line 200 and the showerhead part 13. After the first process gas is adsorbed onto said substrate to be processed, the first process gas remaining in the process space 11A is exhausted through the exhaust port 15. In this case, the process space 11A may be purged by using a purge gas.

Next, a second process gas for reducing said first process gas is supplied to said process space 11A through said gas line and the showerhead part 13, and further a radio frequency electric power is applied to said showerhead part 13 from said radio frequency power source 17 so as to excite plasma of said second process gas. Thus, the dissolution of the second process gas progresses, and the reduction of said first process gas is promoted by radicals and ions generated by the dissolution.

Next, the second process gas remaining in the process space 11A is exhausted from said exhaust port. In this case, the process space 11A may be purged by using a purge gas.

By repeating the above-mentioned process, that is, by repeating the process of supplying and exhausting the first process gas to and from the process space and further supplying and exhausting the second process gas to and from the process space for a predetermined number of times, a thin film of a desired thickness is formed on said substrate W to be processed.

As mentioned above, the film formed by a so-called ALD method has advantages that an amount of impurities in the film is small and has a good film quality.

However, conventionally, there may be a case where an object facing said process space 11A receives a damage such as, for example, being etched by ions and radicals generated when performing plasma excitation in said process space 11A, which results in particles and substances as a pollution source being scattered.

In this case, among portions, which may be made as an object to be etched, facing said process space 11A, especially, said showerhead part 13 is applied with a radio frequency voltage and charged negative and, thereby, an ion bombardment is large and there is a problem in that a rate of sputter etching is large. Thus, in the present embodiment, a process of forming a protective film on a portion, which can be an object to be etched, facing said process space 11A including said showerhead 13 is provided so as to form the protective film, and, thereby, the object such as said showerhead part 13 facing the process space 11A is prevented from being etched, and allowing prevention of scattering of particles and pollution substances.

Since said showerhead part 13 is constituted by a metal material such as, for example, Al, Ni, etc., if Al or Ni scatters by sputter etching, there is a problem in that it acts as a pollution source of the thin film formed on the substrate to be processed. Thus, according to the present embodiment, the protective film is formed so as to cover said showerhead part 13, for example, to cover said shower plate 13B exposed to said process space 11A and, especially, being sputter etched.

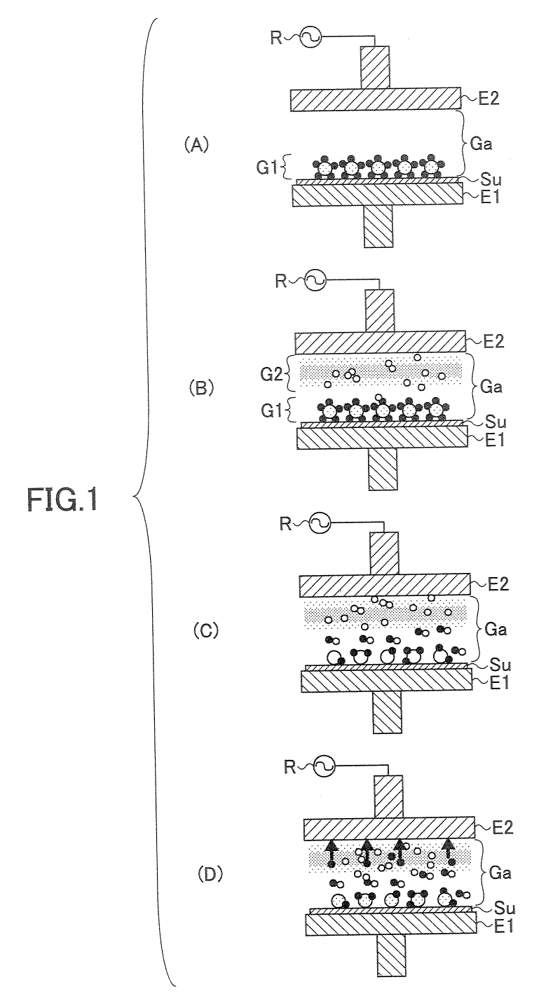

For example, as an active species that etches or sputter-etches said showerhead 13 and the like, there are radicals and ions of halogen contained in metal halide used as, for example, the first process gas. For example, when depositing a Ta film on the substrate to be processed, a halide such as TaCl₅ is used as the first process gas, but there is a remarkable problem in that the showerhead part 13 is etched by halogen radicals or halogen ions, such as, for example, Cl radicals or Cl ions generated by halogen element being activated as indicated in FIG. 1(A)-(D) and especially, the showerhead part 13 is sputter-etched by attack of Cl ions.

Thus, although the protective film, which covers said showerhead part 13, is formed in the present embodiment, it is preferable that the protective film has a sputter-resistance by ions generated in said process container being lager than that of a material constituting said showerhead. In this case, the sputter-etching of said showerhead part 13 can be suppressed efficiently.

Moreover, it is preferable that the protective film has a larger sputtering-resistance by ions generated in said process container than the thin film formed on the substrate to be processed. In this case, when forming the thin film on said substrate to be processed, since the sputtering-resistance of said protective film is larger than the thin film deposited on said showerhead part 13, it is possible to suppress sputter-etching of said showerhead part 13 efficiently.

For example, when forming a Ta film on the substrate to be processed, TaCl₅ is used as the first process gas and H₂ is used as the second process gas, and further the second process gas is used by being plasma-excited. In this case, if a film containing Ti or a Ti film is used as the protective film protecting said showerhead 13, which film is superior to sputtering-resistance, it has a sputtering-resistance higher than Al or Ni, which constitutes the showerhead part 13, and the sputtering-resistance is preferably higher than Ta formed on the showerhead part when performing a deposition process.

Moreover, ions attacking said showerhead part 13 are not limited to the halogen ions such as Cl ions, and, for example, there is a case where Ar ions generated from a gas, such as an Ar gas, supplied to the process container together with the second process gas as a carrier gas, and it is preferable that the sputtering-resistance of the protective film is high with respect to these Ar ions or the like.

For example, a value of a threshold value of a self-bias potential (Vdc) at which a sputtering phenomenon occurs is 7 V for Ni, 13 V for Al and 13 V for Ta, while it is a value as high as 20 V for Ti. (refer to “sputtering phenomenon” written by Kanehara Akira, 1984)

As mentioned above, Ti exhibits a high resistance to Ar sputtering as compared to Al, Ni and Ta. Additionally, it is considered that the resistance of Ti is high with respect to Cl sputtering, and it is appreciated that a Ti film of a film containing Ti is preferable as the protective film of sputtering.

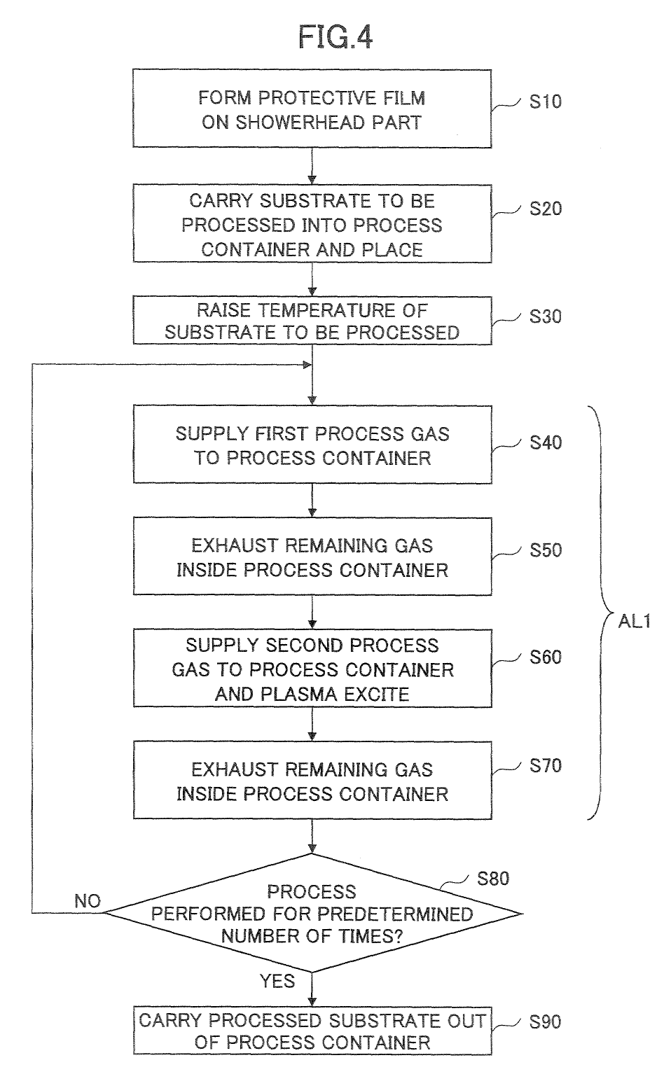

Next, a description will be given, based on a flowchart shown in FIG. 4, of a specific example in a case of carrying out the film deposition method of the present embodiment.

FIG. 4 is a flowchart showing the film deposition method according to the present embodiment. It should be noted that parts previously explained are given the same reference numerals, and descriptions thereof will be omitted.

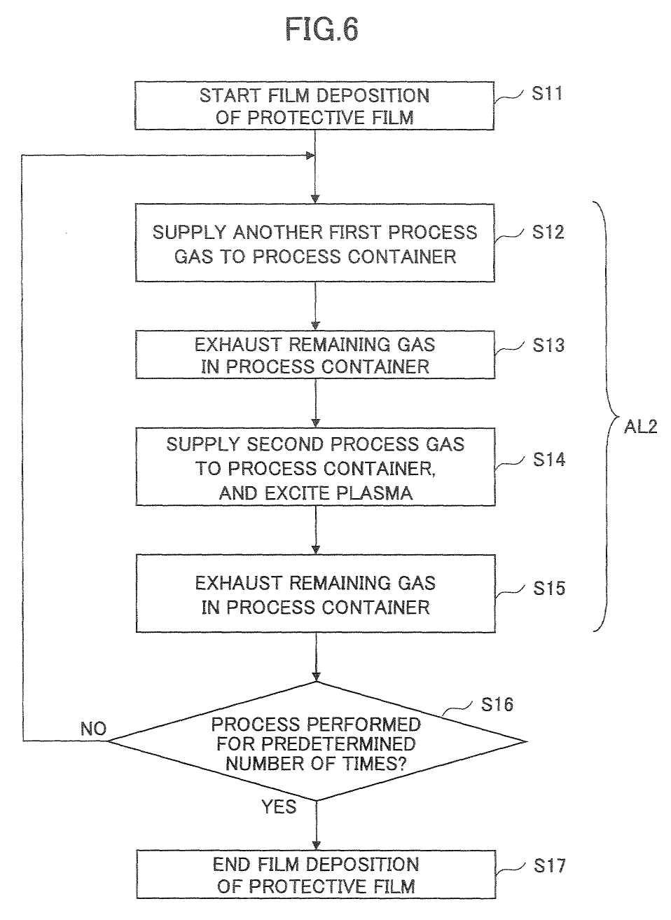

First, in step 10 (represented as S10 in the figure, hereinafter the same applies), before the substrate to be processed is carried into the process container, the protective film made of, for example, a Ti film for protecting the showerhead part 13 from being sputter-etching is formed on a part facing the process space 11A in the process container 11, such as for example the showerhead part 13. In this case, a description will be given later, with reference to FIG. 6, of an example, of details of a protective film forming step shown in step 10.

Next, in step 30, a temperature of said substrate to be processed is raised by a heater incorporated in said holding table 12.

Next, in step 40, said valves 203a, 203b and 203c are opened so that the vaporized TaCl₅ is supplied to said process space 11A from said source material container 204 through said gas line 200 together with Ar supplied from said gas line 205.

In this step, said first process gas is adsorbed on the substrate to be processed by TaCl₅ as said first process gas being supplied onto the substrate to be processed.

Additionally, in this step, Ar as a reverse flow prevention gas may be supplied from said gas line 100 to said process space 11A by opening the valve 102a and the valve 102b and controlling a flow by said mass flow controller 102A so as to prevent the first process gas from flowing reversely from said showerhead part 13 to the side of said gas line 100.

Next, in step 50, the supply of the first process gas to said process space 11A is stopped by closing said valves 203a, 203b and 203c, and exhausting the first process gas, which is not adsorbed onto said substrate to be processed and remaining in said process space 11A, outside said process container 11 from said exhaust port 15. In this case, Ar as a purge gas may be introduced from said gas line 200 and said gas line 100 by opening said valves 201a and 201b and said valves 102a and 102b, respectively, so as to purge said process space 11A. In this case, the remaining first process gas is exhausted immediately from the process space. After a purge of a predetermined time is ended, said valves 201a and 201b and said valves 102a and 102b are closed.

Then, in step 60, H₂ gas as the second process gas is introduced into said process space 11A by opening said valves 101a and 101b and controlling a flow by said mass flow controller 101A, and further, a plasma excitation is performed in said process space 11A by applying a radio frequency electric power (RF) to said showerhead part 13 from said radio frequency power source 17. In this case, H₂ in said process space is diverted and changed into H⁺/H* (hydrogen ions and hydrogen radicals), which react with said first process gas (TaCl₅) adsorbed on said substrate W to be processed. In this case, before exciting plasma, the second process gas may be supplied for a predetermined time so as to stabilize the flow of the second process gas and raise a pressure of the process space.

In the present step, a reaction indicated by

TaCl₅+H₂→Ta+HCl

is generated, and a Ta film is formed on the substrate to be processed.

However, on the other hand, a reaction indicated by

HCl→Cl⁺/Cl*+H⁺/H*

is generated, that is, the formed HCl is excited by plasma, and, for example, Cl⁺/Cl* (Cl ions and Cl radicals) are generated. Although there was a problem in which said showerhead part 13 is etched by these radicals or ions conventionally, since the showerhead part is covered by the protective film made of a Ti film in the present embodiment, it is possible to suppress the etching. Moreover, in this case, the suppressed etching includes both a chemical etching and a physical etching (sputter-etching).

Moreover, in this step, Ar as a reverse flow prevention gas may be supplied to said process space 11A from said gas line 200 by opening the valve 201a and the valve 201b and controlling a flow by said mass flow controller 201A so as to prevent the second process gas from flowing reversely from said showerhead part 13 to the side of said gas line 200. Additionally, when supplying the second process gas, Ar as a carrier gas may be supplied from said gas line 102. There may be a case where the showerhead part 13 is etched by active species (Ar ions or the like) generated by a gas supplied to the process container as a reverse flow prevention gas and a carrier gas such as, for example, Ar being excited, and the protective film is capable of protecting the showerhead from being etched.

Next, in step 70, the supply of the second process gas to said process space 11A is stopped by closing said valves 101a and 101b, and exhausting the second process gas, which is not reacted with said first process gas and remaining in said process space 11A, outside said process container 11 from said exhaust port 15. In this case, Ar as a purge gas may be introduced from said gas line 200 and said gas line 100 by opening said valves 201a and 201b and said valves 102a and 102b, respectively, so as to purge said process space 11A. In this case, the remaining second process gas is exhausted immediately from the process space. After a purge of a predetermined time is ended, said valves 201a and 201b and said valves 102a and 102b are closed.

Next, in step 80, in order to form a thin film of a necessary thickness on the substrate to be processed, the film deposition process is returned to step 40, if necessary, and proceeds to step 90 after repeating a process AL1, which is a film deposition process according to a so-called ALD method consisting of steps 40-70 until a desired film thickness is acquired.

Then, in step 90, said substrate W to be processed is separated from said substrate holding table 12 and is carried out of said process container 11.

As mentioned above, according to the film deposition process according to the present embodiment, a metal film or a film containing metal such as, for example, a Ta film is formed on the substrate to be processed. In this case, the first process gas is not limited to TaCl₅, and other halide gases such as, for example, TaF₅, TaBr₅, TaI₅, etc., may be used, which provides the same effects as TaCl₅ being used.

It should be noted that the Ta film formed in the present embodiment contains at least Ta in the components of the film, and a coupling state thereof is not limited and further additives may be contained. Additionally, a TaN film, a Ta(C)N film may be formed.

Additionally, the metal film or film containing metal formed in the present embodiment has a small amount of impurities and has a high-quality, and since a good coverage characteristic can be obtained when depositing a minute pattern, it is suitable for a diffusion prevention film (a barrier film or an adhesion film) of Cu wiring of a high-performance semiconductor device having minute wiring patterns.

Moreover, the film that can be deposited by the film deposition method according to the present embodiment is not limited to the film containing Ta, and, for example, a film containing Ti, W, etc., may be formed.

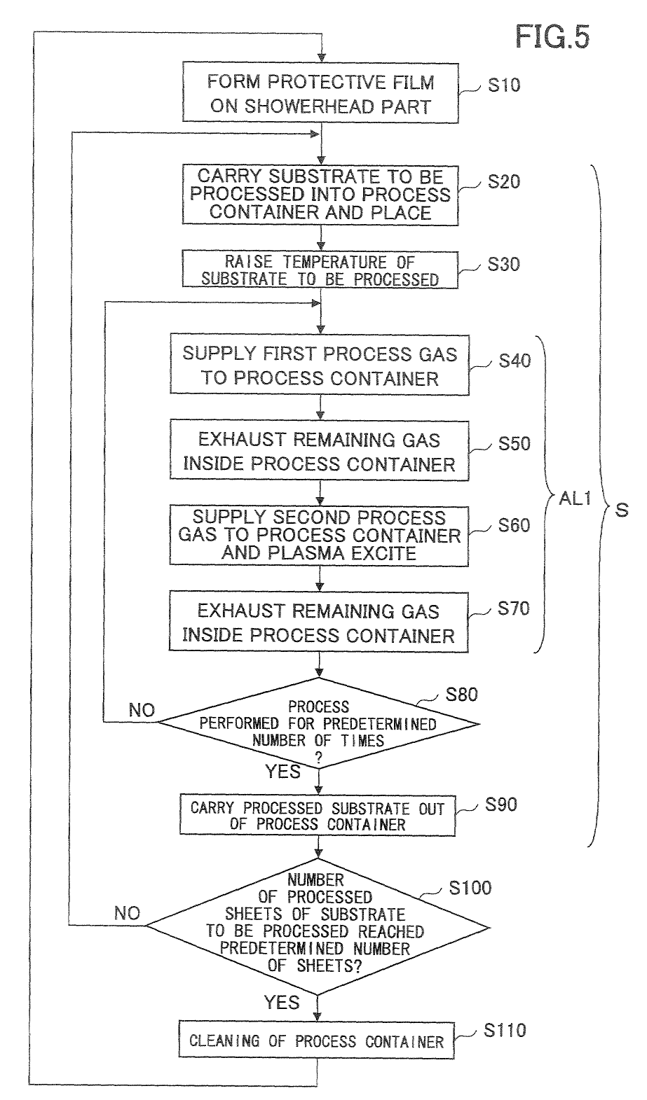

Additionally, although an example of the film deposition method when processing one substrate to be processed, if film deposition is performed on a plurality of substrates to be processed, it is preferable to subject the process container to cleaning after the film deposition is performed so as to remove a thin film deposited on inside the process container. Thus, an example of the film deposition method including a cleaning process is shown in FIG. 5.

FIG. 5 is a flowchart showing an example of the film deposition method including the cleaning process when performing film deposition consecutively on a plurality of substrates. It should be noted that parts explained previously are given the same reference numerals, and descriptions thereof will be omitted.

In the film deposition method shown in the figure, the process proceeds to step 100 after step 90, and it is determined in step 100 whether or not a number of processed sheets reached a predetermined number of sheets, and if the predetermined number of sheets is not reached, the process is returned to step 20 so as to repeat a cycle S from step 20 to step 90. Here, if the process of the predetermined number of sheets is completed and cleaning of inside the process container is needed, the process proceeds from step 100 to step 110 so as to perform cleaning of the process container. The cleaning of the process container can remove a film containing deposited metal such as, for example, a Ta film according to various methods such as plasma-exciting by introducing a fluorocarbon base gas, performing gas cleaning by supplying an active gas, or performing cleaning by opening the process container. When the cleaning inside the process container is completed in this step, the process is returned to step 10 so as to form a protective film inside the process container including the showerhead part 13 again. This is because the protective film is also removed in the cleaning process of step 110.

As mentioned above, based on the flowchart shown in FIG. 5, the process of depositing film consecutively on a plurality of substrates to be processed is carried out. According to the film deposition method according to the present embodiment, scattering of particles and pollution substances is suppressed and a stable and clean film deposition can be made since an amount of etching of members facing inside the process container, such as, for example, the showerhead part, and there also is an effect that a maintenance cycle of the members such as the showerhead part can be elongated and operation rate of the film deposition apparatus is improved since an amount of etching of the members such as the showerhead part is suppressed.

Next, an example of details of the film deposition method with respect to the protective film forming process indicated in step 10 in FIG. 4 and FIG. 5 is shown in FIG. 6

FIG. 6 is a flowchart showing the details of an example of the protective film forming process according to the present embodiment. It should be noted that parts previously explained are given the same reference numerals, and descriptions thereof will be omitted.

First, when a film deposition of a protective film is started in step 11, the protective film is formed inside the process container 11 including a surface of said showerhead part 13 such as a side of said shower plate 13B facing said process space 11A in the same manner as the process AL1 shown in FIGS. 4 and 5, that is from said step 40 to step 70.

Specifically, first, in step 12, said valves 207a, 207b and 207c are opened so that vaporized TiCl₄ is supplied from said source material container 208 to said process space 11A through said gas line 200 together with Ar supplied from said gas line 209.

In this step, as TiCl₄, which is another first process gas different from TaCl₅ as said first process gas is supplied onto the substrate to be processed, the another first process gas is adsorbed onto, for example, said showerhead part.

Additionally, in this step, Ar as a reverse flow prevention gas is supplied to said process space 11A from said gas line 100 by opening the valve 102a and the valve 102b and controlling a flow by said mass flow controller 102A so as to prevent the another first process gas from flowing reversely from said showerhead part 13 to the side of said gas line 100.

Next, in step 13, the supply of the another first process gas to said process space 11A is stopped by closing said valves 207a, 207b and 207c, and exhausting the process gas, which is not adsorbed onto said substrate to be processed and remaining in said process space 11A, outside said process container 11 from said exhaust port 15. In this case, Ar as a purge gas may be introduced from said gas line 200 and said gas line 100 by opening said valves 201a and 201b and said valves 102a and 102b , respectively, so as to purge said process space 11A. In this case, the remaining first process gas is exhausted immediately from the process space. After a purge of a predetermined time is ended, said valves 201a and 201b and said valves 102a and 102b are closed.

Then, in step 14, H₂ gas as the second process gas is introduced into said process space 11A from said gas line by opening said valves 101a and 101b and controlling a flow by said mass flow controller 101A, and further, a plasma excitation is performed in said process space 11A by applying a radio frequency electric power (RE) to said showerhead part 13 from said radio frequency power source 17. In this case, H₂ in said process space is dissolved and changed into H+/H* (hydrogen ions and hydrogen radicals), which react with said another first process gas (TaCl₅) adsorbed on said substrate W to be processed, and, for example, a protective film made of a Ti film is formed inside the process container including said showerhead part 13 such as a surface of said shower plate 13B.

Moreover, in this step, Ar as a reverse flow prevention gas may be supplied to said process space 11A from said gas line 200 by opening the valve 201a and the valve 201b and controlling a flow by said mass flow controller 201A so as to prevent the second process gas from flowing reversely from said showerhead part 13 to the side of said gas line 200. Additionally, when supplying the second process gas, Ar as a carrier gas may be supplied from said gas line 102.

Next, in step 15, the supply of the second process gas to said process space 11A is stopped by closing said valves 101a and 101b, and exhausting the second process gas, which is not reacted and remaining in said process space 11A, outside said process container 11 from said exhaust port 15. In this case, Ar as a purge gas may be introduced from said gas line 200 and said gas line 100 by opening said valves 201a and 201b and said valves 102a and 102b, respectively, so as to purge said process space 11A. In this case, the remaining second process gas is exhausted immediately from the process space. After a purge of a predetermined time is ended, said valves 201a and 201b and said valves 102a and 102b are closed.

Next, in step 16, the film deposition process is returned to step 12 again, if necessary, and proceeds to step 17 after repeating a process AL2, which is a film deposition process according to a so-called ALD method consisting of steps 12-15 until a desired film thickness is acquired. After step 17, the process proceeds to said step 20, for example, as shown in FIG. 4 and FIG. 5.

As mentioned above, according to the process shown in FIG. 6, a metal film or a film containing metal such as, for example, a Ti film is formed on the showerhead and so forth. In this case, the first process gas is not limited to TiCl₄, and other process gases may be used, which provides the same effects as TiCl₄ being used.

It should be noted that the Ti film formed in the present embodiment contains at least Ti in the components of the film, and a coupling state thereof is not limited and further additives may be contained.

Moreover, the protective film formed by a so-called ALD method has a small amount of impurities and high quality, and has an advantage that a resistance to chemical etching and physical etching (sputter-etching) is high.

Additionally, according to the film deposition method shown in the present embodiment, the film deposition method is the same as the thin film formed on the substrate to be processed, and facilities such as gas supply facilities, a control system and software relating to a control can be shared today, and a cost relating to the film deposition can be reduced.

Additionally, if necessary, the characteristics and composition of the protective film and metal to be contained can be used by arbitrarily changing. For example, if a radio frequency electric power for plasma-excitation is large, a film having a further higher sputtering resistance can be formed, if necessary, and, as mentioned above, it is apparent that a protective film corresponding to a film deposition process depositing a film on the substrate to be processed can be formed and used.

### Embodiment 2

Moreover, in order to improve the efficiency of the process of the film deposition apparatus shown in FIG. 2, there is a method of heating said showerhead part 13, and there is a method of controlling a thickness of the thin film deposited on the showerhead part 13, for example, a thickness of the Ta film.

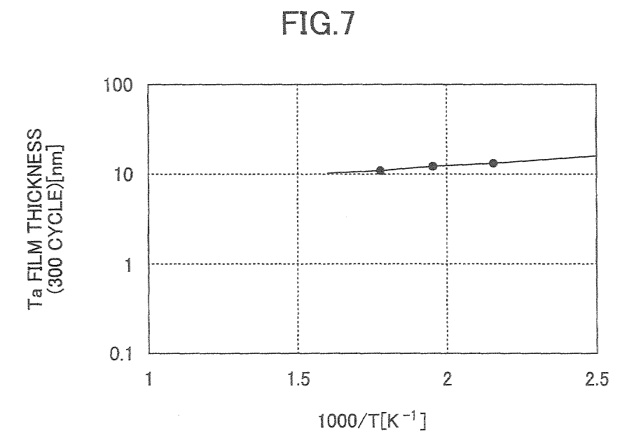

FIG. 7 is a diagram showing a relationship between a film deposition temperature and a film deposition rate of a Ta film deposited, in which the film deposition rate deceases as the film deposition temperature is increased. Thus, it is appreciated that the film thickness of the Ta film deposited becomes thin when the film deposition temperature is high.

By using such a relationship between a temperature and a film deposition rate, it becomes possible to reduce the films thickness of the Ta film deposited on the showerhead part by heating the showerhead by, for example, the heating means 13a shown in FIG. 3.

For example, by heating said showerhead part 13 in said process AL1 shown in FIG. 5, a thickness of the Ta film deposited on the showerhead part can be controlled. Thus, for example, the predetermined number of substrates shown in step 100 of FIG. 5, that is, a number of substrates that can be processed until cleaning is required can be increased, which enables the efficiency of the process of the film deposition apparatus to be good.

Additionally, in this case, since the number of times of forming the protective film is controlled as well, an effect can be provided that the efficiency of the film deposition process becomes good especially when it is used with a combination with the film deposition method for forming the protective film.

Although the preferred embodiments of the present invention were explained in the above, the present invention is not limited to the specifically disclosed embodiments, and various variations and modifications may be made within the scope recited in the claims.

### Embodiment 3

Moreover, in the present invention, for example, the protective film formed on the showerhead part to prevent etching of halogen or the like is not limited to a film containing Ti as indicated above, and other films may also be used.

In this case, it is preferable to use, for example, a film containing Si and C as said protective film. In this case, for example, the film containing Si and C means a film of which major components are Si and C, and may contain other elements such as, for example, H₂. Additionally, although it is possible to form to contain oxygen, since a film containing oxygen has a small etching resistance, it is preferable to make the content of oxygen as small as possible. Hereinafter in the text, the film containing Si and C is referred to as SiC film.

The SiC film concerned is excellent in sputtering resistance, and when it is used as said protective film, it provides an excellent effect to a sputtering resistance for Ar ions and Cl ions. Additionally, the Sic film further has a feature in that it is excellent in a resistance for chemical etching by Cl radicals generated during film deposition, and it is further excellent in the resistance than the above mentioned film containing Ti with respect to the etching resistance by Cl radicals. Thus, it has a feature that it is excellent in both the sputtering by ions generated in a film deposition process and the chemical etching by halogen radicals generated in a film deposition process. Thus, it is excellent in an effect of protecting from etching during a film deposition process, and the effect of preventing pollution source from scattering is large.

For example, especially in a case where the showerhead part may be etched by sputtering by ions, it is possible to use a film containing Ti as a protective film, and further if an influence of the chemical etching such as halogen radicals is large, it is preferable to use a film containing Si and C.

For example, the SiC film can be formed by an apparatus indicated below.

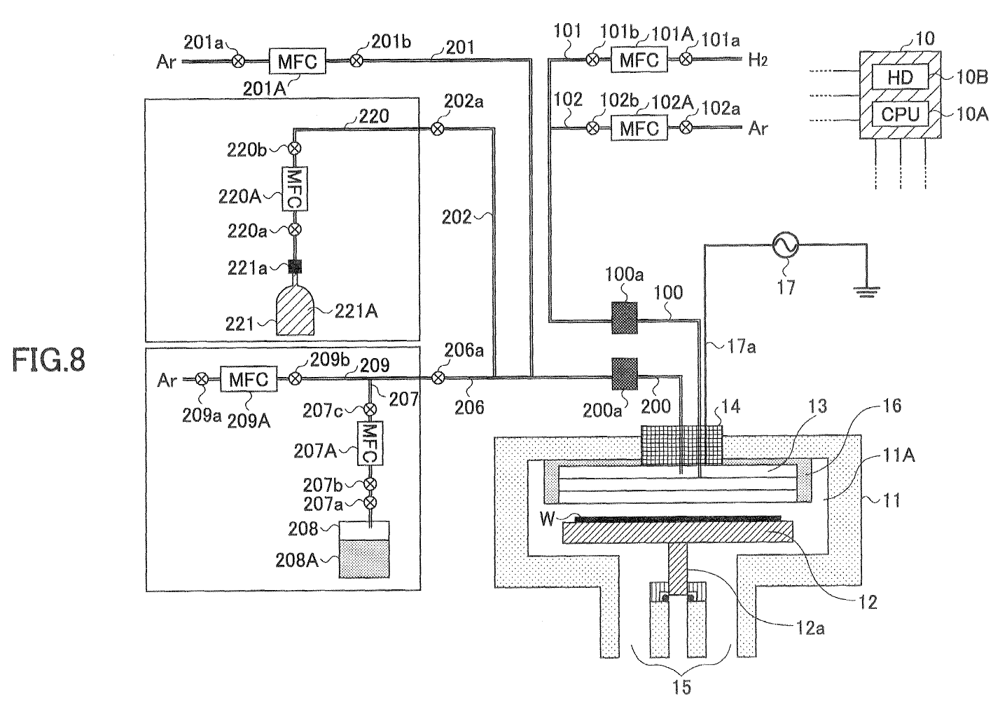

FIG. 8 is a cross-sectional view illustrating the film deposition apparatus according to the present embodiment. It should be noted that parts that are previously explained are given the same references, and descriptions thereof will be omitted. In this case, although the outline of the apparatus is the same as the film deposition apparatus shown in FIG. 2, the film deposition apparatus according to the present embodiment differs in the following points. In the case of film deposition apparatus according to the present embodiment, said gas line 202 is connected to the gas line 220 through said valve 202a. The gas line 220 is connected with a source material gas retaining part 221 having a pressure control valve 221a through valves 220a and 220b and a mass flow controller 220A. A protective film deposition gas 221A for depositing a protective film is retained in the source material gas retaining part 221. Additionally, a source material for forming the SiC film is not limited to a gas at a normal temperature, and a source material which is a liquid or a solid at a normal temperature may be used, if necessary. In the case of the present embodiment, a description is given of said protective film deposition gas 221A by taking a case of using a trimethyle silane gas as an example.

In the film deposition method according to the present embodiment, in the protective film forming process of step 10 shown in FIG. 4 and FIG. 5, said protective film deposition gas 221A is supplied into said process container through said gas line 220 to said gas line 202 and further said showerhead part 13 so as to excite plasma to perform deposition of the protective film.

Specifically, for example, when the protective film forming process is started, first, the protective film deposition gas is supplied into said process container 11 by opening said valves 202a, 220a and 220b and while controlling a flow of said protective film deposition gas 221A by said mass flow controller 220A. Then, plasma is excited by applying a radio frequency electric power to said showerhead part 13 by said radio frequency power source 17 so that the protective film made of an SiC film is formed on the showerhead part 13. Additionally, in this case, a gas such as He may be supplied through said gas line 102 instead of Ar.

Moreover, when forming said protective film to cover said showerhead part 13, it is possible to control a film quality of the formed protective film (SiC film) appropriately by controlling a temperature of said showerhead part 13.

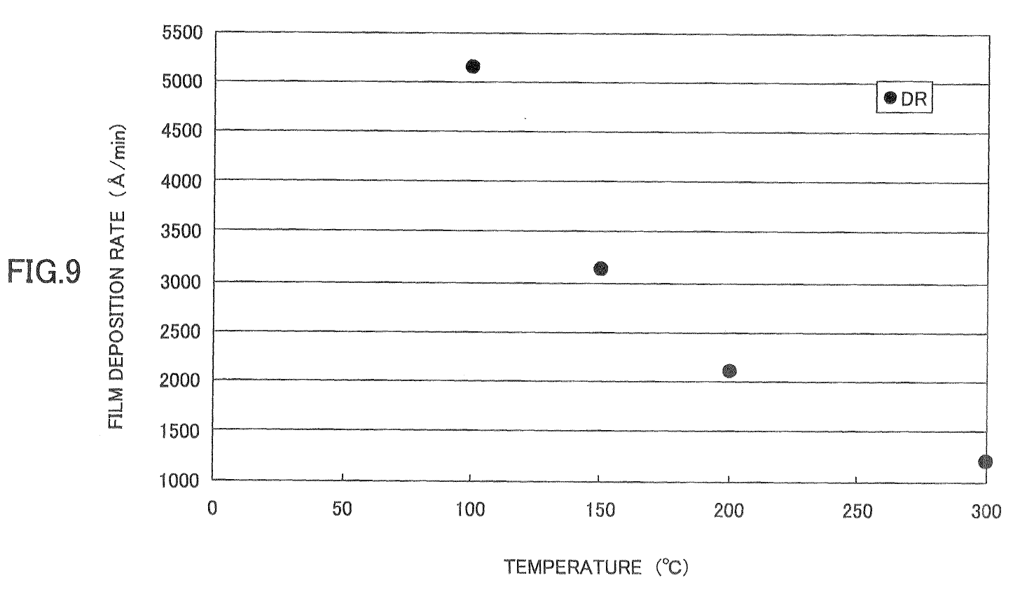

FIG. 9 shows change of film deposition rate to form the SiC film when changing the film deposition temperature. In this case, since it is difficult to directly measure the protective film (SiC film) formed on the showerhead part 13, one formed on the substrate to be processed is measured. However, such a change in the film deposition characteristics with respect to a temperature is the same as in the case of the protective film formed on said showerhead part 13. In this case, the flow of trimethyle silane is 150 sccm, the flow of He is 800 sccm, the radio frequency electric power is 800 W and the pressure inside the process container is 7.8 Torr.

Referring to FIG. 9, it can be appreciated that if the film deposition temperature (in this case, the temperature of the substrate to be processed) rises, the film deposition rate tends to decrease. In this case, the density of the formed protective film (SiC film) is increased by increasing the film deposition rate, and it is considered that a so-called dense film is formed.

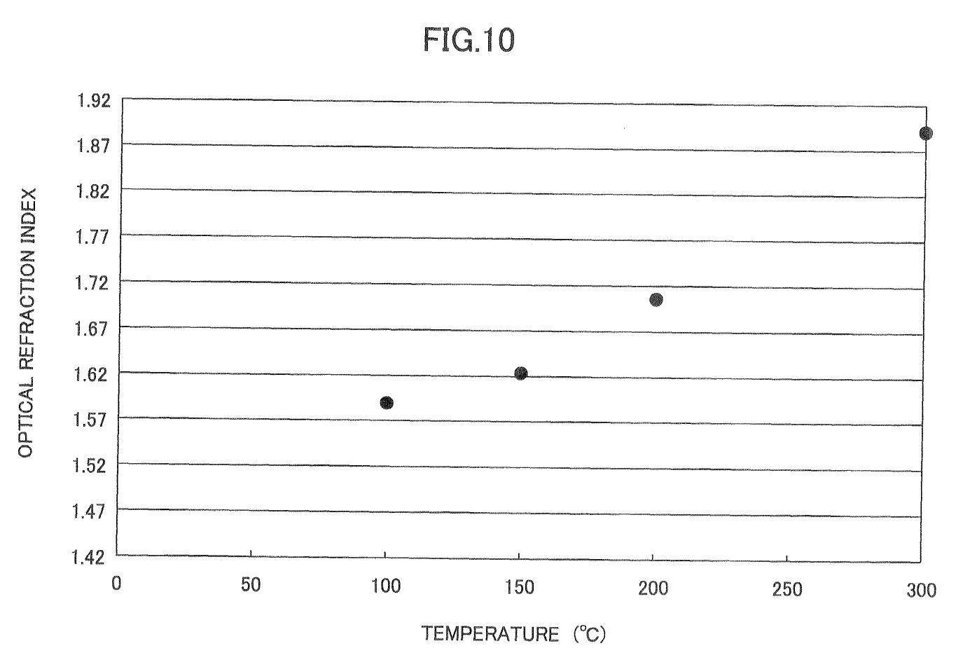

Moreover, FIG. 10 shows a change in an optical refraction index of the SiC film when changing the film deposition temperature. In this case, as the same as the case shown in FIG. 9, the protective film formed on the substrate to be processed is measured.

Referring to FIG. 10, if the film deposition temperature rises, the optical refraction rate increases, and a result is indicated in which it is considered that the density of the protective film is increased as the film deposition temperature rises.

Moreover, when the density of the protective film is increased by raising the film deposition temperature, the protective film becomes dense and it is considered that the etching resistance with respect to halogen ions and halogen radicals becomes excellent. Thus, it is preferable that, for example, the heating means 13a for heating the showerhead part 13 is formed in the showerhead part 13 as shown in FIG. 3. By heating the showerhead part 13 by the heating means 13a, the protective film formed on the showerhead part 13 can be made dense and excellent in etching resistance.

Additionally, on the other hand, since a preferable temperature range of the temperature of said showerhead part 13 is determined from conditions relating to the film deposition in the film deposition process for performing film deposition on the substrate to be processed, it is preferable to be controlled in consideration of those conditions so that an appropriate temperature is achieved.

Additionally, the film deposition method according to the present embodiment can be performed in the same manner as the cases indicated in the embodiment 1 and embodiment 2 except for the above-mentioned process, that is, the protective film forming process. Additionally, according to the film deposition method according to the present embodiment, it is possible to form a film containing Ta or Ti on the substrate to be processed.

For example, when forming Ti on the substrate to be processed, TiC₄ may be used instead of TaCl₅ in said film deposition process AL1 shown in FIG. 4.

Moreover, with respect to the method of forming a Ti film or a Ta film on the substrate to be processed, it is not limited to a so-called ALD method, and it can be formed using other various method such as, for example, a PE-CVD method. In this case, a film containing Ta or Ti can be deposited by exciting plasma by supplying a film deposition gas such as TaCl₅ or TiCl₄ and a reduction gas such as H₂ or NH₃ to the process container simultaneously or by changing the supply timing. Additionally, a film containing Ta or Ti can be deposited using various gases in addition to those gases.

For example, when forming a film containing Ti on a substrate to be processed, TiCl₄, Ar, H₂, NH₃, etc., may be used as a gas for film deposition. In this case, a film containing Ti can be formed on the substrate to be processed by arranging the film deposition process to include a plurality of steps, if necessary, and repeating the plurality of steps while changing a period or a flow of gas to be supplied or changing a radio frequency electric power to be applied.

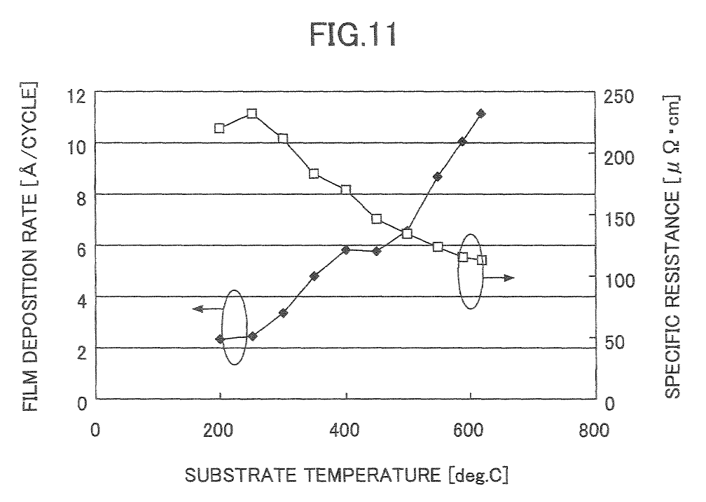

For example, FIG. 11 shows a film deposition rate and a specific resistance value when a temperature of a substrate to be processed is changed in a case where Ti is formed on the substrate to be processed by using TiCl₄, Ar, H₂ and NH₃ for the gases for carrying out the film deposition.

In this case, the step of film deposition includes a first step and a second step, and in the first step, TiCl₄, Ar, and H₂ are supplied to the process container by 2.5 sccm, 750 sccm and 1500 sccm, respectively, and the radio frequency electric power is applied by 350 W. In the second step, NH₃, Ar and H₂ are supplied to the process container by 200 sccm, 750 sccm and 1500 sccm, respectively, and the radio frequency electric power is applied by 550 W. Additionally, in this case, the first step and the second step are repeated to perform film deposition in accordance with a necessary film thickness.

Thus, according to the film deposition method according to the present embodiment, a film containing Ta or a film containing Ti can be formed on a substrate to be processed. Additionally, in this case, it is possible to form a film having high purity with suppressed impurities since scattering of pollution substances from the showerhead part is suppressed due to the protective film containing Si and C being formed on the showerhead part.

Additionally, it is possible to make said protective film to be a structure in which a film containing Ti and an SiC film are stacked. For example, it is possible to use as the protective film a lamination structure such as Ti/SiC or SIC/Ta, or a lamination structure Ti/SiC/Ti or SiC/Ti/SiC, and further those structures may be used in combination. In this case, an etching prevention effect of a showerhead is large, and a scattering prevention effect of impurities is excellent.

Although the preferred embodiments of the present invention are explained above, the present invention is not limited to the above-mentioned specific embodiments, and various variations and modifications may be made within the scope recited in the claims.

### INDUSTRIAL APPLICABILITY

According to the present invention, when depositing a film on a substrate to be processed by using process gas by being plasma-excited, scattering of a pollution source of film deposition is suppressed and clean and stable film deposition can be made.

The present international application claims priority based on Japanese patent application No. 2004-367789 filed Dec. 20, 2004, the entire contents of which are hereby incorporated herein by reference

1. A film deposition method by a film deposition apparatus that comprises: a process container having therein a holding table for holding a substrate to be processed; and a gas supply part configured to be capable of being applied with a radio frequency electric power so as to supply a film deposition gas or a reduction gas for reducing the film deposition gas into said process container, the film deposition method comprising:
a first step of supplying said film deposition gas containing a metal element and a halogen element into said process container;
a second step of supplying said reduction gas into said process container; and
a third step of performing film deposition on said substrate to be processed by applying a radio frequency electric power to said gas supply part to excite plasma in said process container,
the film deposition method further provided with a protective film forming step of forming a protective film that protects said gas supply part from etching of said halogen element that is activated in said third step.

2. The film deposition method as claimed in claim 1, wherein said first step includes a step of exhausting said film deposition gas from said process container, and said second step includes a step of exhausting said reduction gas from said process container.

3. The film deposition method as claimed in claim 1, wherein said third step is a step of plasma-exciting said reduction gas.

4. The film deposition method as claimed in claim 2, wherein said film deposition is performed by repeating said first step through said third step.

5. The film deposition method as claimed in claim 1, wherein said protective film contains Ti.

6. The film deposition method as claimed in claim 5, wherein said metal element is Ta.

7. The film deposition method as claimed in claim 1, wherein said protective film forming step includes:
a fourth step of supplying a protective film deposition gas from said gas supply part into said process container and exhaust the gas; and
a fifth step of supplying a reduction gas for reducing the protective film deposition gas from said gas supply part into said process container, and plasma-exciting said reduction gas by a radio frequency electric power applied to said gas supply part,
wherein the forth and fifth steps are repeated alternately.

8. The film deposition method as claimed in claim 1, wherein said protective film is a film containing Si and C.

9. The film deposition method as claimed in claim 8, wherein said protective film forming step includes:
a sixth step of supplying a protective film deposition gas containing Si and C from said gas supply part into said process container; and
a seventh step of plasma-exciting said protective film deposition gas by a radio frequency electric power applied to said gas supply part.

10. The film deposition method as claimed in claim 8, wherein said metal element is Ti or Ta.

11. The film deposition method as claimed in claim 8, wherein said film deposition gas contains one of TaCl₅, TaF₅, TaBr₅ and TaI₅.

12. The film deposition method as claimed in claim 9, wherein said protective film deposition gas is made of an organic silane gas.

13. The film deposition method as claimed in claim 1, wherein said gas supply part is heated by heating means.

14. The film deposition method as claimed in claim 1, including a cleaning step of removing deposition in said process container before said protective film forming step.

15. The film deposition method as claimed in claim 1, wherein said substrate to be processed is not placed on said holding table in said protective film forming step.

16. A recording medium storing a program for causing a computer to operate a film deposition method by a film deposition apparatus that comprises: a process container having therein a holding table for holding a substrate to be processed; and a gas supply part configured to be capable of being applied with a radio frequency electric power so as to supply a film deposition gas or a reduction gas for reducing the film deposition gas into said process container, the film deposition method comprising:
a first step of supplying said film deposition gas containing a metal element and a halogen element into said process container;
a second step of supplying said reduction gas into said process container; and
a third step of performing film deposition on said substrate to be processed by applying a radio frequency electric power to said gas supply part to excite plasma in said process container,
the film deposition method further provided with a protective film forming step of forming a protective film that protects said gas supply part from etching of said halogen element that is activated in said third step.
